(19) United States
(12) Patent Application Publication
(10) Pub. No.: US 2025/0203864 A1
(43) Pub. Date: Jun. 19, 2025

(54) SEMICONDUCTOR DEVICE INCLUDING ELECTRODE AND ISOLATION PATTERN AND METHOD OF FORMING THE SAME

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Na Yeong YANG, Icheon-si Gyeonggi-do (KR); Jung Shik JANG, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 18/647,687

(22) Filed: Apr. 26, 2024

(30) Foreign Application Priority Data
Dec. 13, 2023 (KR) 10-2023-0181003

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80006; H01L 2224/80895; H01L 2224/80896; H01L 2924/1431; H01L 2924/14511

(57) ABSTRACT

A semiconductor device may include a stack structure bonded onto a circuit structure and including a plurality of molding layers alternately stacked with a plurality of electrodes. A source line may be disposed on the stack structure. A channel structure extending into the source line through the stack structure may be provided. An isolation insulating pattern disposed in a slit that extends through the source line and the stack structure may be provided. The isolation insulating pattern may include a first section adjacent to the source line and a second section adjacent to the stack structure. The isolation insulating pattern may include a convergence interface between the first section and the second section. The convergence interface may be disposed between an end of the channel structure and an end of the plurality of electrodes.

### CROSS-REFERENCE TO RELATED APPLICATION

The present application claims priority under 35 U.S.C. § 119 (a) to Korean Patent Application No. 10-2023-0181003 filed in the Korean Intellectual Property Office on Dec. 13, 2023, which application is incorporated herein by reference in its entirety.

### BACKGROUND

### 1. Technical Field

Various embodiments of the disclosed technology generally relate to a semiconductor device including, but not limited to, an electrode and an isolation pattern and a method of forming the same.

### 2. Related Art

In response to the demand for high integration of a semiconductor device, a technology for bonding two wafers exists. Bonding between a lower wafer and an upper wafer may use coupling between insulating layers. Electrical connection between the lower wafer and the upper wafer may use coupling between bonding pads disposed in the insulating layers. Physical deformation such as warpage of the upper wafer causes a decrease in the yield of a bonding process and the bonded wafers.

### SUMMARY

In an embodiment, a semiconductor device may include a stack structure bonded onto a circuit structure and including a plurality of molding layers alternately stacked with a plurality of electrodes. A source line may be disposed on the stack structure. A channel structure extending into the source line through the stack structure may be provided. An isolation insulating pattern disposed in a slit that extends through the source line and the stack structure may be provided. The isolation insulating pattern may include a first section adjacent to the source line and a second section adjacent to the stack structure. The isolation insulating pattern may include a convergence interface between the first section and the second section. The convergence interface may be disposed between an end of the channel structure disposed in the source line and a surface of the plurality of electrodes closest to the source line.

In an embodiment, a semiconductor device may include a stack structure on a substrate. The stack structure may include a plurality of molding layers alternately stacked with a plurality of electrodes. A source line may be disposed on the stack structure. A channel structure extending into the source line through the stack structure may be provided. An isolation insulating pattern disposed in a slit that extends through the source line and the stack structure may be provided. The isolation insulating pattern may include a first section adjacent to the source line and a second section adjacent to the stack structure. A side surface of the isolation insulating pattern may include a convergence interface between the first section and the second section. The convergence interface may be disposed between an end of the channel structure disposed in the source line and a surface of the plurality of electrodes closest to the source line.

### BRIEF DESCRIPTION OF THE DRAWINGS

FIG. 1 is a cross-sectional view illustrating a semiconductor device based on an embodiment of the disclosed technology.

FIG. 2 through FIG. 8 are partial views illustrating sections of FIG. 1 according to various embodiments.

FIG. 9 is a flow chart illustrating a method of forming a semiconductor device based on an embodiment of the disclosed technology.

FIG. 10 through FIG. 25 are cross-sectional views and plan views of a semiconductor device formed utilizing the method of forming a semiconductor device based on various embodiments of the disclosed technology.

The cross-hatching throughout the figures illustrates corresponding or similar areas between the figures rather than indicating the materials for the areas.

### DETAILED DESCRIPTION

Various embodiments of the disclosed technology are directed to providing a semiconductor device that has excellent electrical characteristics and is advantageous for increasing mass production efficiency and a method of forming the same.

Terms such as “vertical,” “horizontal,” “upper,” “lower,” “uppermost,” “lowermost,” “above,” “bottom,” and other terms implying specific spatial relationship and/or orientation are provided only for ease of description or reference and are not otherwise limiting.

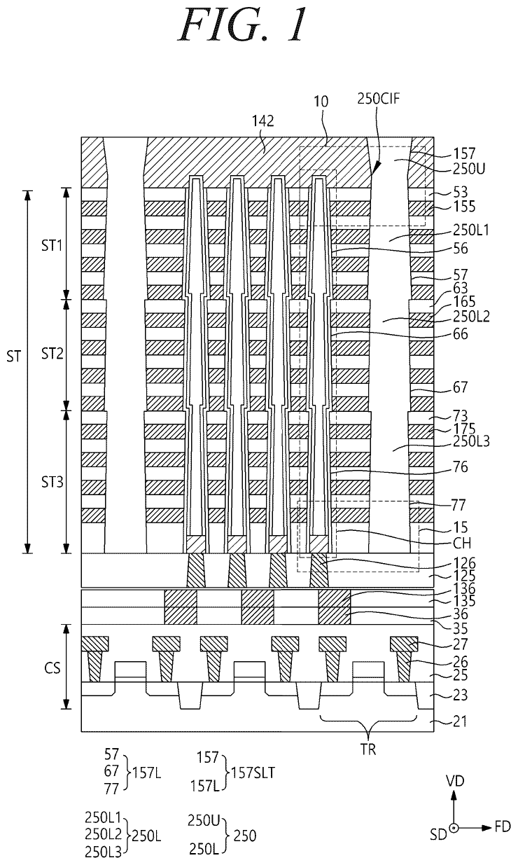

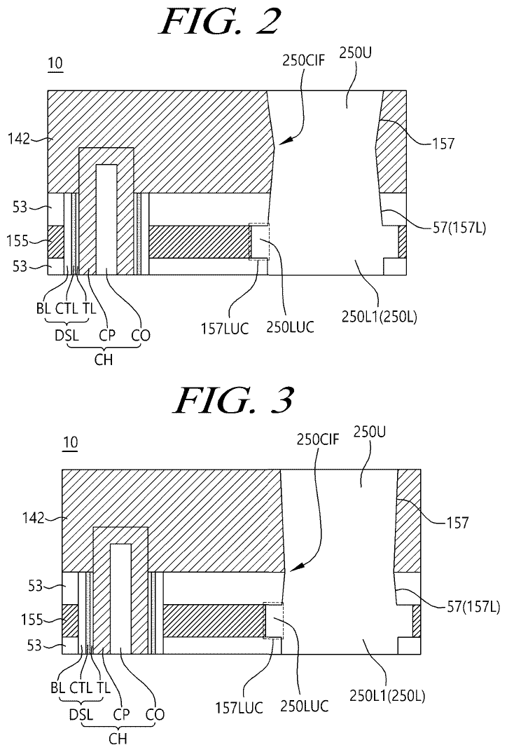

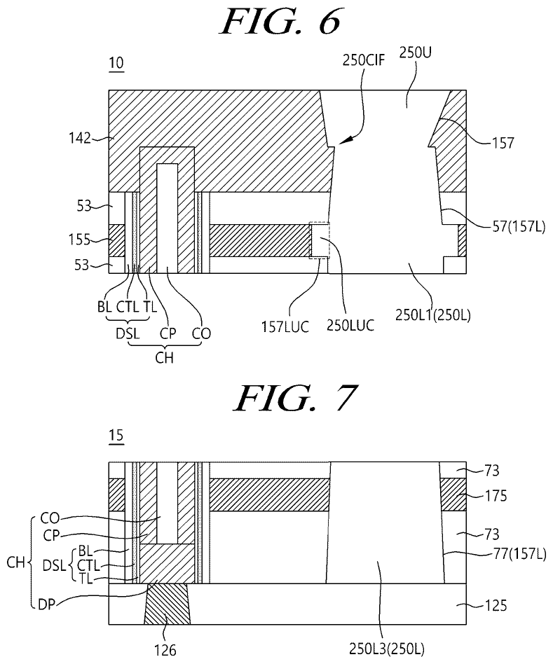

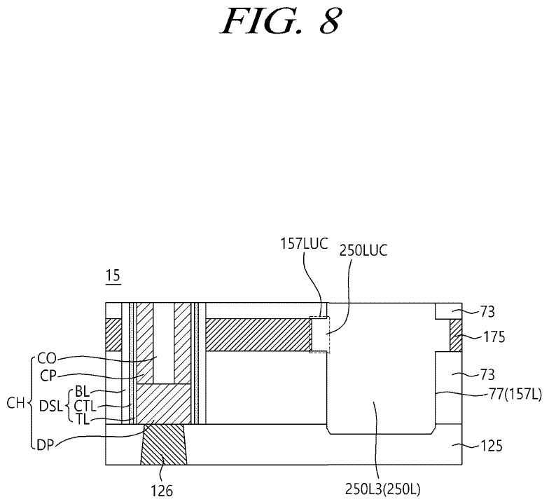

FIG. 1 is a cross-sectional view illustrating a semiconductor device based on an embodiment of the disclosed technology, FIG. 2 through FIG. 6 are partial views illustrating section 10 of FIG. 1, and FIG. 7 and FIG. 8 are partial views illustrating section 15 of FIG. 1.

Referring to FIG. 1, the semiconductor device based on the embodiment of the disclosed technology includes a circuit structure CS on a first substrate 21. The circuit structure CS includes an isolation layer 23, a transistor TR, a circuit insulating layer 25, a vertical interconnection 26, and a horizontal interconnection 27. A first insulating bonding layer 35 and a first bonding pad 36 are disposed on the circuit structure CS.

A first direction FD, a second direction SD and a third direction VD are shown for ease of reference with respect to the drawing orientation. The first direction FD and the second direction SD are parallel to the upper surface and/or the lower surface of the first substrate 21. The second direction SD is perpendicular to the first direction FD. The third direction VD is perpendicular to the first direction FD and the second direction SD. The third direction VD is perpendicular to the upper surface and/or the lower surface of the first substrate 21.

A second insulating bonding layer 135 is bonded onto the first insulating bonding layer 35 in the third direction VD in this example. A second bonding pad 136 is bonded to the first bonding pad 36. The second bonding pad 136 is disposed in the second insulating bonding layer 135. An interlayer insulating layer 125 and an interconnection 126 are disposed on the second insulating bonding layer 135 and the second bonding pad 136. A stack structure ST is disposed on the interlayer insulating layer 125 and the interconnection 126.

A source line 142 is disposed on the stack structure ST. A channel structure CH extends into the source line 142 through the stack structure ST in the third direction VD. An isolation insulating pattern 250 is disposed in a slit 157SLT that extends through the source line 142 and the stack structure ST in the third direction VD. The upper surface of the source line 142 and the upper surface of the isolation insulating pattern 250 are formed in substantially the same plane. The lower surface of the isolation insulating pattern 250 contacts the interlayer insulating layer 125.

The stack structure ST includes a first stack structure ST1, a second stack structure ST2, and a third stack structure ST3. The first stack structure ST1 includes a plurality of first molding layers 53 alternately stacked with a plurality of first horizontal electrodes 155. The second stack structure ST2 includes a plurality of second molding layers 63 alternately stacked with a plurality of second horizontal electrodes 165. The third stack structure ST3 includes a plurality of third molding layers 73 alternately stacked with a plurality of third horizontal electrodes 175. Molding layers are also known as insulating layers, and horizontal electrodes are also known as electrodes or conductive layers.

As illustrated in FIG. 2 through FIG. 8, the channel structure CH includes a core layer CO that extends into the source line 142 through the stack structure ST, a channel pattern CP that surrounds the side surface and the upper surface of the core layer CO, an information storage pattern DSL between the channel pattern CP and the stack structure ST, and a bit plug DP that contacts the core layer CO and the channel pattern CP at one end of the channel structure CH as shown in FIG. 8. The information storage pattern DSL includes a tunnel layer TL disposed on the channel pattern CP, a charge trap layer CTL disposed on the tunnel layer TL, and a blocking layer BL disposed on the charge trap layer CTL. The charge trap layer CTL is disposed between the tunnel layer TL and the blocking layer BL.

The slit 157SLT completely extends through the source line 142 and the entire stack structure ST in the third direction VD as shown in FIG. 1. The slit 157SLT includes an upper slit 157 and a lower slit 157L. The lower slit 157L is open, joined, or contiguous with the upper slit 157. The upper slit 157 extends at least partially through the source line 142 in the third direction VD. The upper slit 157 may have an inverted trapezoid shape.

The lower slit 157L extends through the stack structure ST in the third direction VD. The lower slit 157L includes a first lower slit 57, a second lower slit 67, and a third lower slit 77. The first lower slit 57, the second lower slit 67, and the third lower slit 77 are open, joined, or contiguous with each other. The first lower slit 57 extends through the first stack structure ST1. The first lower slit 57 may have a trapezoid shape. The second lower slit 67 extends through the second stack structure ST2. The second lower slit 67 may have a trapezoid shape. The third lower slit 77 extends through the third stack structure ST3. The third lower slit 77 may have a trapezoid shape.

The isolation insulating pattern 250 includes an upper section 250U, also referred to as a first section, and a lower section 250L, also referred to as a second section. The lower section 250L may be contiguous with the upper section 250U in the third direction VD. The upper section 250U is disposed in the upper slit 157. The upper section 250U may have an inverted trapezoid shape. The lower section 250L is disposed in the lower slit 157L.

The lower section 250L includes a first lower section 250L1, a second lower section 250L2 and a third lower section 250L3. The first lower section 250L1, the second lower section 250L2 and the third lower section 250L3 may be contiguous with each other. The first lower section 250L1 is disposed in the first lower slit 57. The first lower section 250L1 may have a trapezoid shape. The second lower section 250L2 is disposed in the second lower slit 67. The second lower section 250L2 may have a trapezoid shape. The third lower section 250L3 is disposed in the third lower slit 77. The third lower section 250L3 may have a trapezoid shape.

The side surface of the isolation insulating pattern 250 includes a convergence interface 250CIF between the upper section 250U and the lower section 250L. The convergence interface 250CIF is disposed between a level at the uppermost end of the channel structure CH and a level at the upper surface of the uppermost horizontal electrode 155, which upper surface is closest to the source line 142.

In the examples of FIG. 1 through FIG. 8, the source line 142 corresponds to a common source line. The plurality of horizontal electrodes 155, 165, and 175 include a plurality of word lines, a plurality of select lines, and at least one GIDL (gate induced drain leakage) control line. A plurality of memory cells are formed at intersections of the channel structure CH and the plurality of word lines.

In an embodiment, at least one of the plurality of horizontal electrodes 155, 165, and 175 closest to the source line 142 corresponds to a source select line. At least one of the plurality of horizontal electrodes 155, 165, and 175 closest to the bit plug DP corresponds to a drain select line. One of the plurality of horizontal electrodes 155, 165, and 175 closest to the source line 142 and/or one of the plurality of horizontal electrodes 155, 165, and 175 closest to the bit plug DP corresponds to the GIDL control line. A plurality of word lines is disposed between at least one drain select line and at least one source select line among the plurality of horizontal electrodes 155, 165, and 175.

Referring to FIG. 2, the convergence interface 250CIF is disposed at a horizontal level at the uppermost end of the channel structure CH. The upper section 250U of the isolation insulating pattern 250 is contiguous with the lower section 250L. The side slope of the upper section 250U and the side slope of the lower section 250L of the isolation insulating pattern 250 may be different from each other. In an embodiment, the convergence interface 250CIF may be disposed at a horizontal level lower than the uppermost end of the channel structure CH.

The channel structure CH includes the core layer CO, the channel pattern CP, and the information storage pattern DSL. The information storage pattern DSL includes the tunnel layer TL, the charge trap layer CTL, and the blocking layer BL. The channel pattern CP surrounds the side surface and the upper surface of the core layer CO. The information storage pattern DSL surrounds the side surface of the channel pattern CP. The channel pattern CP and the core layer CO may extend into the source line 142. The channel pattern CP may directly contact the source line 142. The uppermost end of the information storage pattern DSL extends no further or terminates at the lowermost surface of the source line 142.

The information storage pattern DSL is disposed between the channel pattern and the plurality of first molding layers 53 alternately stacked with the plurality of first horizontal electrodes 155. The charge trap layer CTL is disposed between the tunnel layer TL and the blocking layer BL. The tunnel layer TL is disposed between the charge trap layer CTL and the channel pattern CP. The blocking layer BL is disposed between the charge trap layer CTL and the plurality of first molding layers 53 alternately stacked with the plurality of first horizontal electrodes 155.

An undercut area 157LUC that is open, joined, or contiguous with the lower slit 157L is formed between consecutive first molding layers 53. The lower section 250L of the isolation insulating pattern 250 includes a side extension 250LUC that extends into the undercut area 157LUC. The side extension 250LUC contacts a side surface of the first horizontal electrode 155.

Referring to FIG. 3, the convergence interface 250CIF is disposed at a horizontal level where the uppermost surface of the plurality of first molding layers 53 contacts the lowermost surface of the source line 142.

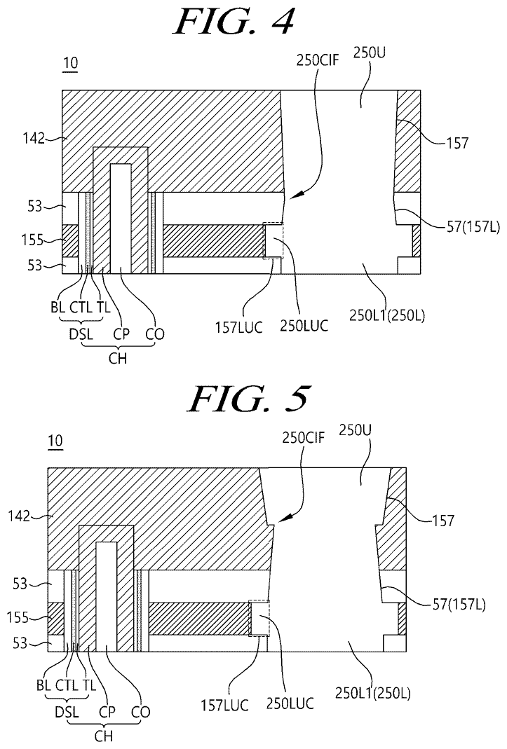

Referring to FIG. 4, the convergence interface 250CIF is disposed at a level above the uppermost surface of the plurality of first horizontal electrodes 155. In an embodiment, the convergence interface 250CIF is disposed between the uppermost surface of the plurality of first horizontal electrodes 155 and the lowermost surface of the source line 142.

Referring to FIG. 5, the upper section 250U and the lower section 250L of the isolation insulating pattern 250 may have different horizontal widths where the upper section 250U is adjacent to the lower section 250L. A horizontal width is a width in the first direction FD. The upper section 250U of the isolation insulating pattern 250 has a horizontal width larger than the width of the lower section 250L at the intersection of the upper section 250U and the lower section 250L. The upper section 250U of the isolation insulating pattern 250 may have an inverted trapezoid shape, and the lower section 250L of the isolation insulating pattern 250 may have a trapezoid shape. The convergence interface 250CIF may include a step.

Referring to FIG. 6, the center of the upper section 250U of the isolation insulating pattern 250 is offset from the center of the lower section 250L. Referring to FIG. 1 and FIG. 6, a straight line that passes vertically through the center of the upper section 250U of the isolation insulating pattern 250 and extends in the third direction VD is offset from a straight line that passes vertically through the center of the lower section 250L of the isolation insulating pattern 250 in the third direction VD. The convergence interface 250CIF may include a step.

Referring to FIG. 7, the lowermost end of the lower section 250L of the isolation insulating pattern 250 is disposed at a horizontal level where the lowermost end of the plurality of third molding layers 73 and the lowermost end of the bit plug DP are located. The lowermost end of the lower section 250L of the isolation insulating pattern 250 is disposed at a horizontal level at the boundary between the lowermost surface of the plurality of third molding layers 73 and the interlayer insulating layer 125.

The channel structure CH includes the core layer CO, the channel pattern CP, the information storage pattern DSL, and the bit plug DP. The information storage pattern DSL includes the tunnel layer TL, the charge trap layer CTL, and the blocking layer BL. The bit plug DP directly contacts the core layer CO and the channel pattern CP. The bit plug DP contacts the interconnection 126.

Referring to FIG. 8, the lowermost end of the lower slit 157L extends into the interlayer insulating layer 125. The lowermost end of the lower section 250L of the isolation insulating pattern 250 extends into the interlayer insulating layer 125. The lowermost end of the lower slit 157L is disposed at a level lower than the uppermost surfaces of the interlayer insulating layer 125 and the interconnection 126. The lowermost end of the lower section 250L of the isolation insulating pattern 250 is disposed at a level lower than the uppermost surfaces of the interlayer insulating layer 125 and the interconnection 126. The lowermost end of the lower section 250L of the isolation insulating pattern 250 is disposed at a level lower than the boundary between the bit plug DP and the interconnection 126.

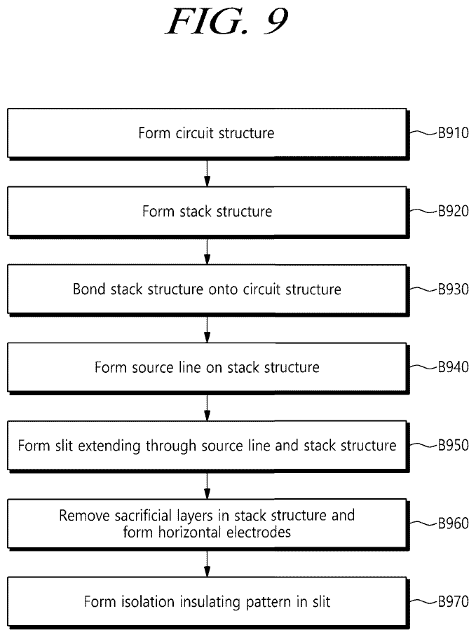

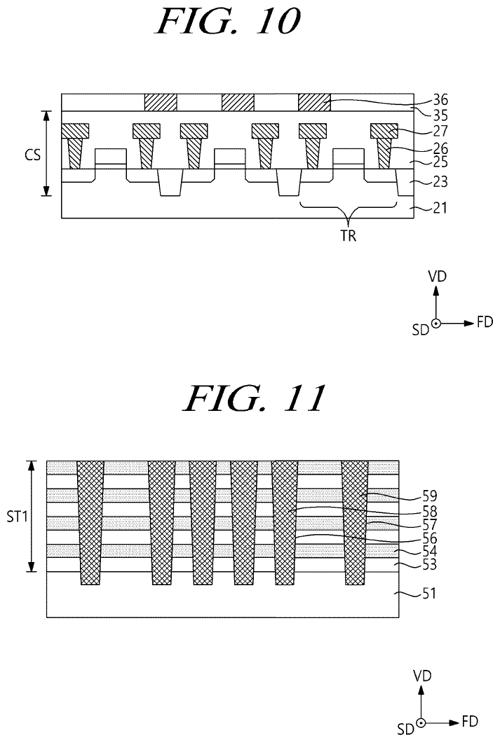

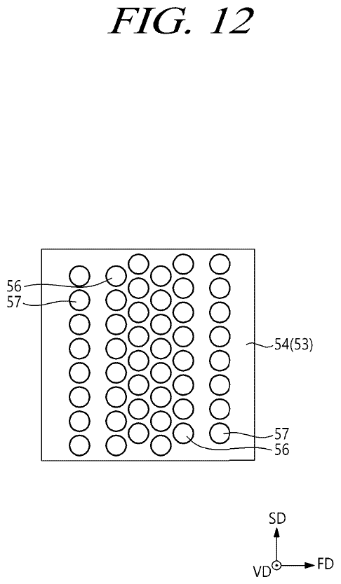

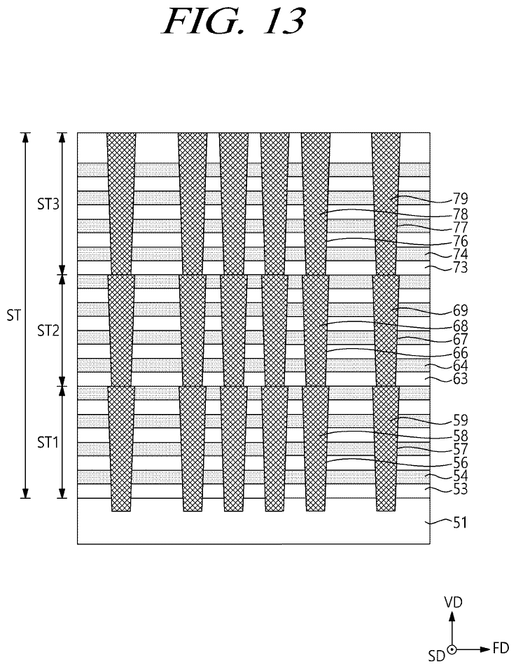

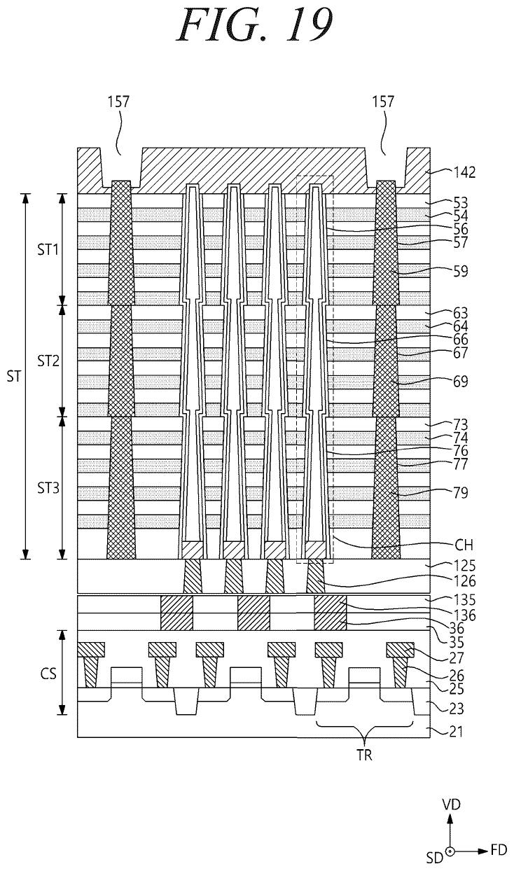

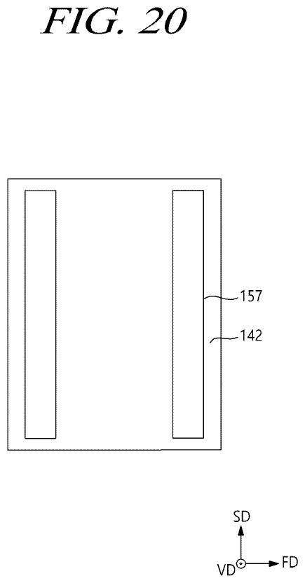

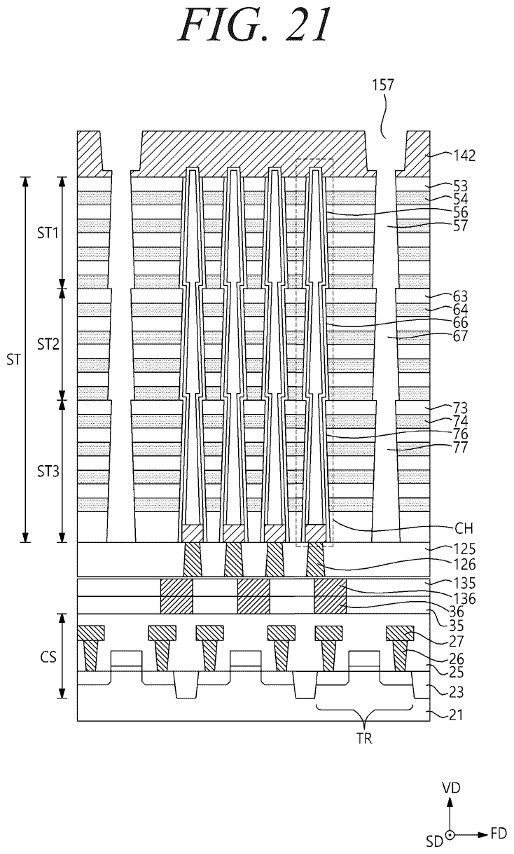

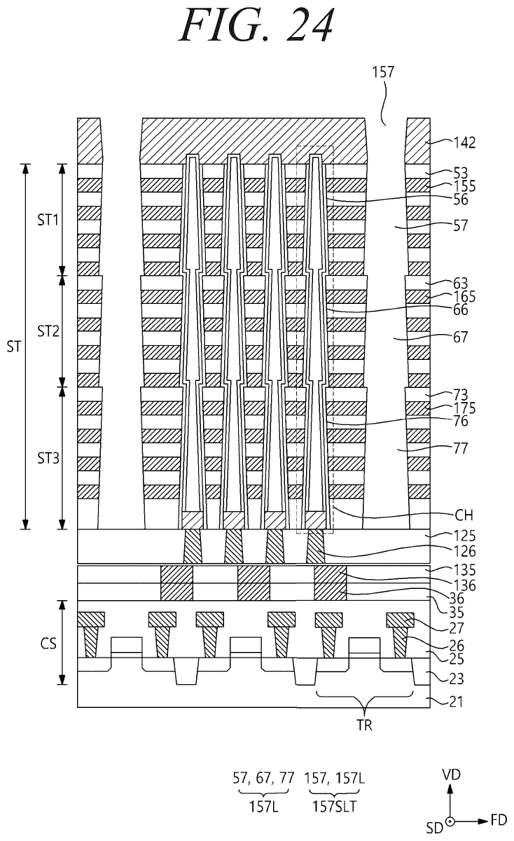

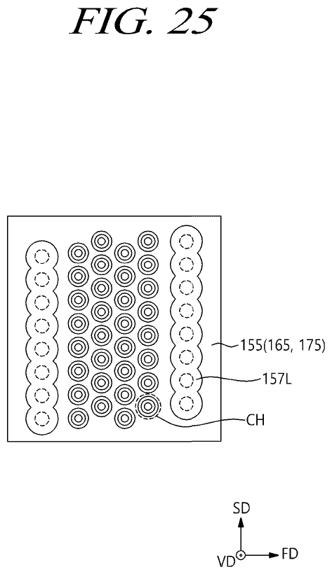

FIG. 9 is a flow chart illustrating a method of forming a semiconductor device based on an embodiment of the disclosed technology. FIG. 10, FIG. 11, FIG. 13 through FIG. 19, and FIG. 21 through FIG. 24 are cross-sectional views of the semiconductor device. FIG. 12, FIG. 20, and FIG. 25 are plan views of the semiconductor device corresponding to FIG. 11, FIG. 19, and FIG. 24, respectively.

Referring to FIG. 9, the method of forming a semiconductor device based on an embodiment of the disclosed technology include forming B910 a circuit structure, forming B920 a stack structure, bonding B930 the stack structure onto the circuit structure, forming B940 a source line on the stack structure, forming B950 a slit extending through the source line and the stack structure, removing B960 sacrificial layers in the stack structure, and forming B970 horizontal electrodes, and forming an isolation insulating pattern in the slit.

Referring to FIG. 9 and FIG. 10, a circuit structure CS is formed B910 on a first substrate 21. The circuit structure CS includes an isolation layer 23, a transistor TR, a circuit insulating layer 25, a vertical interconnection 26, and a horizontal interconnection 27. A first insulating bonding layer 35 is formed on the circuit structure CS. A first bonding pad 36 is formed in the first insulating bonding layer 35. The upper surfaces of the first insulating bonding layer 35 and the first bonding pad 36 are exposed and are formed in substantially the same plane.

The first substrate 21 includes a semiconductor substrate such as a silicon wafer or an SOI (silicon on insulator) wafer. The first substrate 21 may include a III-V group semiconductor substrate, for example, a compound semiconductor substrate such as gallium arsenide GaAs. The first substrate 21 may include monocrystalline silicon, polysilicon, amorphous silicon, monocrystalline silicon germanium, polycrystalline silicon germanium, carbon-doped silicon, or a combination thereof. The circuit structure CS is formed in and/or on the first substrate 21.

The circuit structure CS includes various types of active/passive elements, for example, one or more transistors TR. The transistors TR may be a planar transistor, a recess channel transistor, a vertical transistor, a fin field effect transistor (finFET), a gate all around (GAA) transistor, a multi-bridge channel transistor, or a combination thereof. In an embodiment, the transistor may be part of a peripheral circuit such as a page buffer or a decoder.

The isolation layer 23 may be formed in the first substrate 21 using a shallow trench isolation (STI) method. The transistor TR may be delimited on the first substrate 21 by the isolation layer 23. The circuit insulating layer 25 covers the isolation layer 23 and the transistor TR. The vertical interconnection 26 and the horizontal interconnection 27 are formed in the circuit insulating layer 25. The vertical interconnection 26 and the horizontal interconnection 27 are connected to the transistor TR. The first bonding pad 36 is connected to the transistor TR through the vertical interconnection 26 and the horizontal interconnection 27.

Each of the isolation layer 23, the circuit insulating layer 25, and the first insulating bonding layer 35 may be single layer or multilayer. Each of the isolation layer 23, the circuit insulating layer 25, and the first insulating bonding layer 35 may include at least two selected from the group consisting of silicon Si, oxygen O, nitrogen N, carbon C, and boron B. Each of the isolation layer 23, the circuit insulating layer 25, and the first insulating bonding layer 35 may include silicon oxide, silicon nitride, silicon oxynitride, silicon carbonitride (SiCN), silicon oxycarbonitride (SiOCN), low-k dielectric, high-k dielectric, or a combination thereof. In an embodiment, the first insulating bonding layer 35 may include silicon carbonitride (SiCN).

Each of the vertical interconnection 26, the horizontal interconnection 27, and the first bonding pad 36 may be single layer or multilayer. Each of the vertical interconnections 26, the horizontal interconnections 27, and the first bonding pads 36 may comprise a conductive material such as metal, metal nitride, metal oxide, metal silicide, polysilicon, conductive carbon, or a combination thereof. Each of the vertical interconnections 26, the horizontal interconnections 27, and the first bonding pads 36 may comprise a conductive material such as copper Cu, aluminum Al, nickel Ni, cobalt Co, ruthenium Ru, tungsten W, tungsten nitride WN, titanium Ti, titanium nitride TiN, tantalum Ta, tantalum nitride TaN, tin Sn, platinum Pt, gold Au, silver Ag, or a combination thereof. In an embodiment, the first bonding pad 36 may include a Cu layer that is formed using an electroplating method.

Referring to FIG. 9 and FIG. 11, a first stack structure ST1, in which a plurality of first molding layers 53 alternately stacked with a plurality of first sacrificial layers 54, is formed on or over a second substrate 51. A first channel hole 56 and a first lower slit 57 are formed and extend into the second substrate 51 through the first stack structure ST1. A first channel sacrificial layer 58 is formed in each first channel hole 56, and a first slit sacrificial layer 59 is formed in each first lower slit 57.

The plurality of first sacrificial layers 54 includes a material that has an etch selectivity different than the etch selectivity of the plurality of first molding layers 53. In an embodiment, the plurality of first molding layers 53 may include insulating oxide such as silicon oxide, and the plurality of first sacrificial layers 54 may include nitride such as silicon nitride. The lowermost layer of the first stack structure ST1 may be one of the plurality of first molding layers 53, and the uppermost layer of the first stack structure ST1 may be one of the plurality of first sacrificial layers 54 and the plurality of first molding layers 53.

Each of the first channel hole 56 and the first lower slit 57 extends into the second substrate 51 through the first stack structure ST1 in the third direction VD. The first channel sacrificial layer 58 and the first slit sacrificial layer 59 include materials different from the materials of the plurality of first sacrificial layers 54 and the plurality of first molding layers 53. In an embodiment, the first channel sacrificial layer 58 and the first slit sacrificial layer 59 may include polysilicon, carbon, or metal.

Referring to FIG. 9 and FIG. 12, a plurality of first channel holes 56 are arranged at regular intervals in the first direction FD and the second direction SD. A plurality of first lower slits 57 are arranged at regular intervals in the second direction SD. In an embodiment, the first lower slits 57 may have a similar size and shape as the first channel holes 56.

Referring to FIG. 9 and FIG. 13, a second stack structure ST2 in which a plurality of second molding layers 63 alternately stacked with a plurality of second sacrificial layers 64 are formed on or over the first stack structure ST1. A second channel hole 66 and a second lower slit 67 are formed through the second stack structure ST2. A second channel sacrificial layer 68 is formed in each second channel hole 66, and a second slit sacrificial layer 69 is formed in each second lower slit 67.

A third stack structure ST3 in which a plurality of third molding layers 73 alternately stacked with a plurality of third sacrificial layers 74 are formed on or over the second stack structure ST2. A third channel hole 76 and a third lower slit 77 are formed through the third stack structure ST3. A third channel sacrificial layer 78 is formed in each third channel hole 76, and a third slit sacrificial layer 79 is formed in each third lower slit 77.

As described above, the first stack structure ST1, the second stack structure ST2, and the third stack structure ST3 in combination form B920 a stack structure ST. The first channel hole 56, the second channel hole 66, and the third channel hole 76 are open, joined, or contiguous with each other in the third direction VD. Components included in the second stack structure ST2 and the third stack structure ST3 may be formed using a similar method used to form the first stack structure ST1. Components included in the second stack structure ST2 and the third stack structure ST3 may include materials substantially the same as the materials included in the first stack structure ST1. The uppermost layer of the third stack structure ST3 is one of the plurality of third molding layers 73. The uppermost layer of the third stack structure ST3 corresponds to the uppermost layer of the stack structure ST. The lowermost layer of the first stack structure ST1 corresponds to the lowermost layer of the stack structure ST.

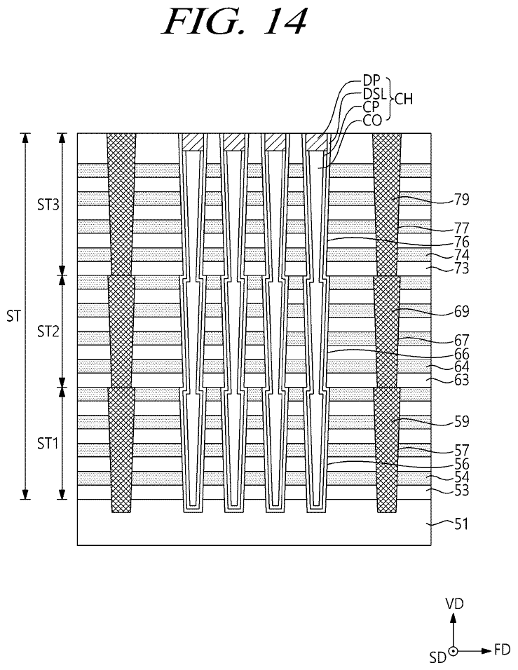

Referring to FIG. 9 and FIG. 14, the third channel sacrificial layer 78, the second channel sacrificial layer 68 and the first channel sacrificial layer 58 are removed, and a channel structure CH is formed in the first channel hole 56, the second channel hole 66, and the third channel hole 76. The channel structure CH extends into the second substrate 51 through the stack structure ST in the third direction VD. The sacrificial layers 58, 68, and 78 may be removed using an etching process, for example.

The channel structure CH includes a core layer CO, a channel pattern CP, an information storage pattern DSL, and a bit plug DP. As illustrated in FIG. 7, the information storage pattern DSL includes a tunnel layer TL, a charge trap layer CTL, and a blocking layer BL. The channel pattern CP is formed to surround the side surface and the end of the core layer CO disposed in the second substrate 51. The information storage pattern DSL is formed to surround the side surface and the end of the channel pattern CP disposed in the second substrate 51. The channel pattern CP is disposed between the core layer CO and the information storage pattern DSL. The bit plug DP is formed on the channel pattern CP and the core layer CO. The bit plug DP directly contacts the core layer CO and the channel pattern CP. The channel structure CH may be formed within the stack ST, for example, by forming the outermost layer first and forming each consecutive layer toward the innermost layer, such as forming, in order, the blocking layer BL, the charge trap layer CTL, the tunnel layer TL, the channel pattern CP, and the core layer CO, after which the bit plug DP is formed. The blocking layer BL, the charge trap layer CTL, the tunnel layer TL, the channel pattern CP, and the core layer CO are each contiguous throughout the stack ST, as shown in the figures.

In an embodiment, the core layer CO may include silicon oxide, silicon nitride, silicon oxynitride, polysilicon, or a combination thereof. The channel pattern CP may include a semiconductor material such as polysilicon. The bit plug DP may include a semiconductor material such as polysilicon. The tunnel layer TL may include silicon oxide, the charge trap layer CTL may include silicon nitride, and the blocking layer BL may include silicon oxide.

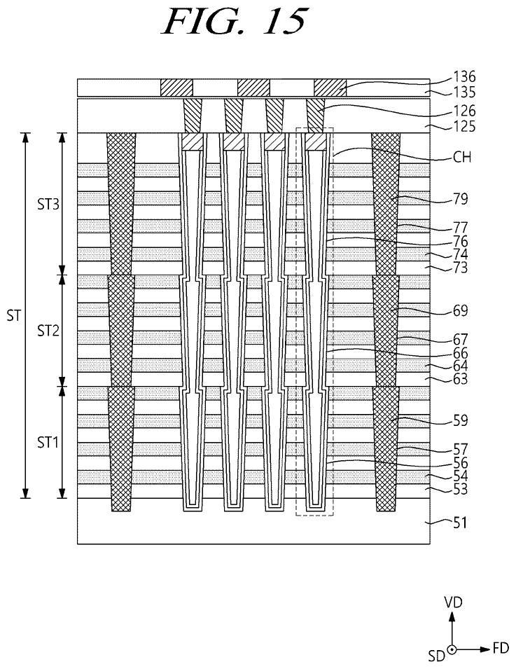

Referring to FIG. 9 and FIG. 15, an interlayer insulating layer 125 is formed on or over the stack structure ST. One or more interconnections 126 are formed in the interlayer insulating layer 125. A second insulating bonding layer 135 is formed on or over the interlayer insulating layer 125 and the interconnections 126. Second bonding pads 136 are formed in the second insulating bonding layer 135. The upper surfaces of the second insulating bonding layer 135 and the second bonding pads 136 are exposed and are formed in substantially the same plane.

The interconnection 126 directly contacts the bit plug DP. The interconnection 126 may include a vertical interconnection in the third direction VD and/or a horizontal interconnection in the first direction FD. In an embodiment, the interconnection 126 includes a bit line. The second bonding pad 136 is electrically connected to the bit plug DP through the interconnection 126.

Each of the interlayer insulating layer 125 and the second insulating bonding layer 135 may be single layer or multilayer. Each of the interlayer insulating layer 125 and the second insulating bonding layer 135 may include at least two selected from the group consisting of Si, O, N, C and B. Each of the interlayer insulating layer 125 and the second insulating bonding layer 135 may include silicon oxide, silicon nitride, silicon oxynitride, silicon carbonitride (SiCN), silicon oxycarbonitride (SiOCN), low-k dielectric, high-k dielectric, or a combination thereof. In an embodiment, the second insulating bonding layer 135 includes silicon carbonitride (SiCN).

Each of the interconnections 126 and the second bonding pads 136 may be single layer or multilayer. Each of the interconnections 126 and the second bonding pads 136 may comprise a conductive material such as metal, metal nitride, metal oxide, metal silicide, polysilicon, conductive carbon, or a combination thereof. Each of the interconnection 126 and the second bonding pad 136 may comprise a conductive material such as Cu, Al, Ni, Co, Ru, W, WN, Ti, TiN, Ta, TaN, Sn, Pt, Au, Ag, or a combination thereof. In an embodiment, the second bonding pads 136 include a Cu layer that is formed using an electroplating method.

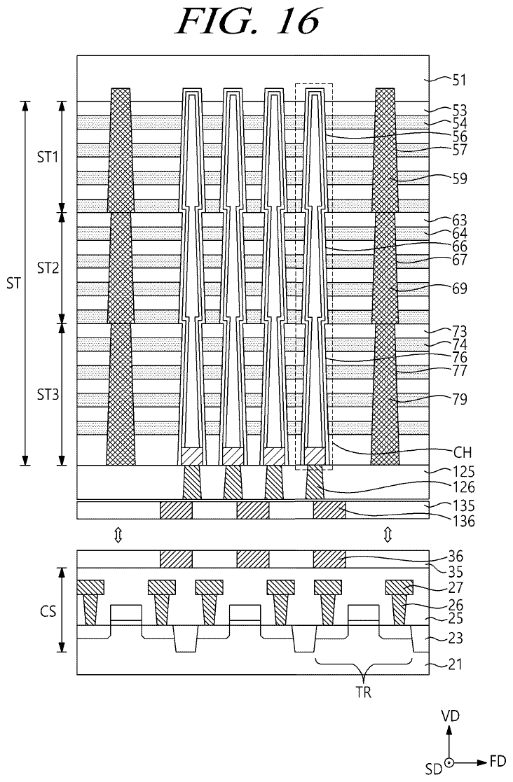

Referring to FIG. 9 and FIG. 16, the second substrate 51 that includes the stack structure ST is bonded B930 onto the first substrate 21 that includes the circuit structure CS. The second insulating bonding layer 135 faces the first insulating bonding layer 35, and each of the second bonding pads 136 faces each of the first bonding pads 36. The first substrate 21 and the second substrate 51 may be formed on separate semiconductor wafers.

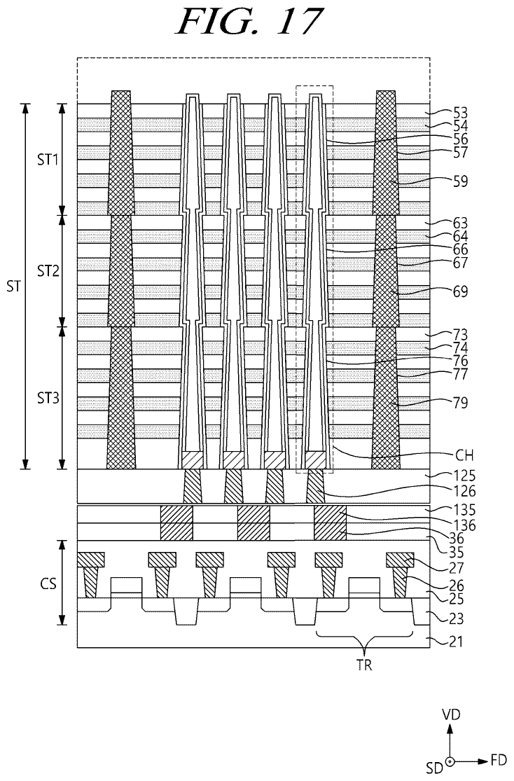

Referring to FIG. 9 and FIG. 17, the second insulating bonding layer 135 is bonded onto the first insulating bonding layer 35. The second bonding pads 136 are bonded onto the first bonding pads 36. The first slit sacrificial layer 59 and the channel structure CH are exposed by removing the second substrate 51. The channel pattern CP is exposed by removing an uppermost part of the information storage pattern DSL.

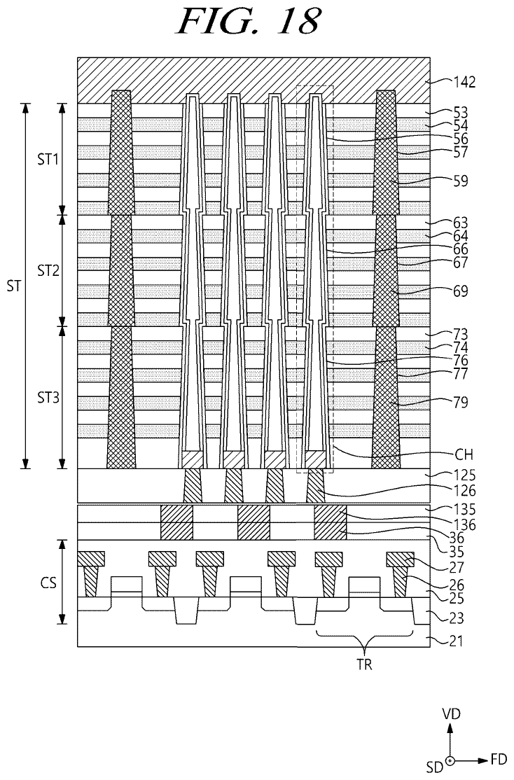

Referring to FIG. 9 and FIG. 18, a source line 142 is formed B940 on the stack structure ST. The source line 142 directly contacts the channel pattern CP. The first slit sacrificial layer 59 extends into the source line 142 in the third direction VD.

The source line 142 may be single layer or multilayer. The source line 142 may include a conductive material such as polysilicon, metal, metal silicide, metal nitride, or a combination thereof. In an embodiment, the source line 142 may include a semiconductor material such as polysilicon.

Referring to FIG. 9 and FIG. 19, by patterning the source line 142, an upper slit 157 that is open, joined, or contiguous with the first lower slit 57 is formed B950. The first slit sacrificial layer 59 is exposed in the upper slit 157. As illustrated in FIG. 2 through FIG. 6, the upper slit 157 may be formed having various depths and shapes.

In an embodiment, the bottom of the upper slit 157 is formed at a level lower in the third direction VD than the level of the uppermost end of the first slit sacrificial layer 59 as shown in FIG. 19. The bottom of the upper slit 157 may be formed at a level lower in the third direction VD than the level of the uppermost surface of the channel structure CH. The bottom of the upper slit 157 may be formed at a horizontal level the same as the level of the uppermost surface of the channel structure CH. The bottom of the upper slit 157 may be formed at a level higher in the third direction VD than the level of the uppermost end of the plurality of first sacrificial layers 54. The bottom of the upper slit 157 may be formed at a level higher in the third direction VD than the level of the upper surface of the stack structure ST. The bottom of the upper slit 157 may be formed at a level higher in the third direction VD than the level of the lowermost end of the source line 142.

Referring to FIG. 9 and FIG. 20, the upper slit 157 extends in the second direction SD within the source line 142. In a plan view including the first direction FD and the second direction SD, the aspect ratio of the upper slit 157 may be 100 times to 1e+100 times comparing the measurement of the upper slit 157 in the second direction SD to the measurement of the upper slit 157 in the first direction FD.

Referring to FIG. 9 and FIG. 21, the lower slit 157L is formed B950, including a first lower slit 57, a second lower slit 67, and a third lower slit 77 open, joined, or contiguous with the upper slit 157, when the first slit sacrificial layer 59, the second slit sacrificial layer 69, and the third slit sacrificial layer 79 are removed. The sacrificial layers 59, 69, and 79 may be removed using an etching process, for example.

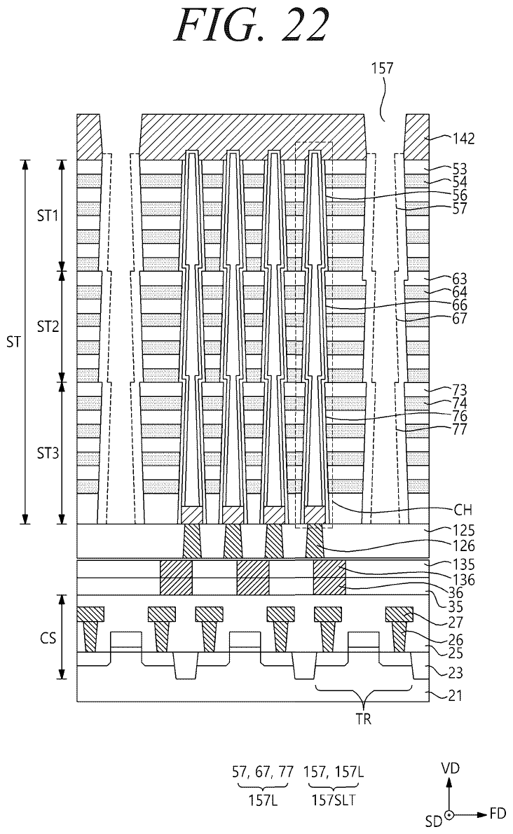

Referring to FIG. 9, FIG. 22, and FIG. 25, the first lower slit 57, the second lower slit 67, and the third lower slit 77 are expanded radially in an embodiment. The first lower slit 57, the second lower slit 67, and the third lower slit 77 form the lower slit 157L. The upper slit 157 and the lower slit 157L form the slit 157SLT. The lower slit 157L is open, joined, or contiguous with the upper slit 157. A plurality of first lower slits 57 aligned in the second direction SD as illustrated in FIG. 12 are open, joined, or contiguous with each other after performing lateral expansion, including expansion in the first direction FD and the second direction SD or expansion in the radial direction. The plurality of first lower slits 57 may be expanded using an etching process, for example. Prior to expansion, the dashed lines in FIG. 22 and FIG. 25 show the shape of the lower slits 57, 67, and 77, and the solid lines show the shape of the lower slits 57, 67, and 77 after expansion. A plurality of second lower slits 67 and a plurality of third lower slits 77 may be expanded using a method similar to the method used to expand the first lower slits 57 and are open, joined, or contiguous with each other in the second direction SD.

The slit 157SLT extends completely through the source line 142 and the stack structure ST in the third direction VD. The edges of each of the plurality of first sacrificial layers 54, the plurality of second sacrificial layers 64, and the plurality of third sacrificial layers 74 are exposed in the lower slit 157L.

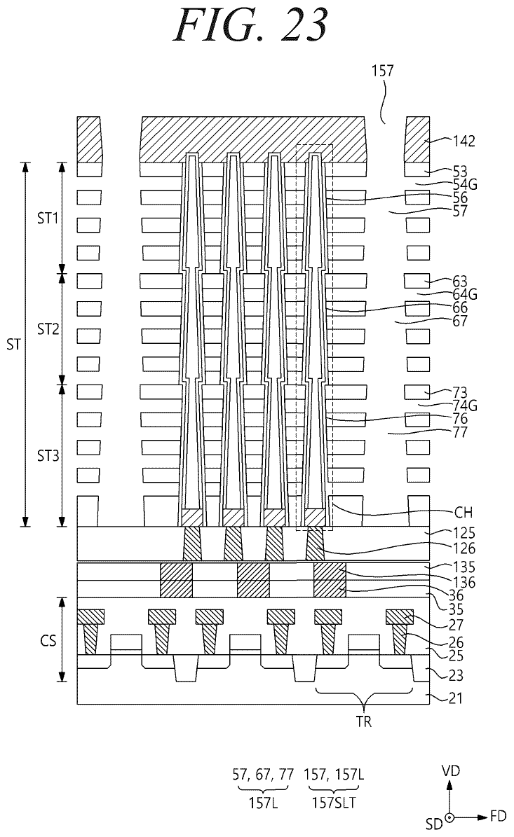

Referring to FIG. 9 and FIG. 23, a plurality of gap areas 54G, 64G, and 74G are formed by removing B960 the plurality of first sacrificial layers 54, the plurality of second sacrificial layers 64, and the plurality of third sacrificial layers 74. The plurality of gap areas 54G, 64G, and 74G include a plurality of first gap areas 54G, a plurality of second gap areas 64G, and a plurality of third gap areas 74G. The sacrificial layers 54, 64, and 74 may be removed using an etching process, for example.

Referring to FIG. 9 and FIG. 24, a plurality of horizontal electrodes 155, 165, and 175 are formed B960 in the plurality of gap areas 54G, 64G, and 74G. The plurality of horizontal electrodes 155, 165, and 175 include a plurality of first horizontal electrodes 155, a plurality of second horizontal electrodes 165, and a plurality of third horizontal electrodes 175.

Each of the plurality of horizontal electrodes 155, 165, and 175 may be single layer or multilayer. The plurality of horizontal electrodes 155, 165, and 175 may comprise a conductive material such as metal, metal nitride, metal oxide, metal silicide, polysilicon, conductive carbon, or a combination thereof. The plurality of horizontal electrodes 155, 165, and 175 may comprise a conductive material such as W, WN, Ti, TiN, Ta, TaN, Ru, or a combination thereof. In an embodiment, the plurality of horizontal electrodes 155, 165, and 175 includes W.

Referring to FIG. 9 and FIG. 25, the lower slit 157L extends in the second direction SD. In a plan view including the first direction FD and the second direction SD, the aspect ratio of the lower slit 157L may be 100 times to 1e+100 times comparing the measurement of the upper slit 157 in the second direction SD to the measurement of the upper slit 157 in the first direction FD. The side walls of the lower slit 157L may have a wave shape in the second direction SD.

Referring to FIG. 9 and FIG. 1, an isolation insulating pattern 250 is formed B970 in the slit 157SLT. The upper surface of the source line 142 and the upper surface of the isolation insulating pattern 250 are formed in substantially the same plane. The isolation insulating pattern 250 includes an upper section 250U and a lower section 250L. The lower section 250L is contiguous with the upper section 250U in the third direction VD. The lower section 250L may include a first lower section 250L1, a second lower section 250L2, and a third lower section 250L3.

The isolation insulating pattern 250 may be single layer or multilayer. The isolation insulating pattern 250 may comprise a material including at least two selected from the group consisting of Si, O, N, C and B. The isolation insulating pattern 250 may comprise silicon oxide, silicon nitride, silicon oxynitride, silicon carbonitride (SiCN), silicon oxycarbonitride (SiOCN), low-k dielectric, high-k dielectric, or a combination thereof.

According to the embodiment of the disclosed technology, the stack structure ST is bonded B930 onto the circuit structure CS, and after removing the sacrificial layers 54, 64, and 74 in the stack structure ST, the horizontal electrodes 155, 165, and 175 are formed B960. Physical deformation such as warpage may be relatively reduced in the stack structure ST by utilizing the sacrificial layers 54, 64, and 74 and the second substrate 51 in the formation of the horizontal electrodes 155, 165, and 175 after bonding the stack structure ST onto the circuit structure CS. Bonding defects may also be reduced when warping is reduced. Because bonding B930 of the stack structure ST, formed on the second substrate 51, onto the circuit structure CS, formed on the first substrate 21, is performed prior to forming B960 the horizontal electrodes 155, 165, and 175, the coupling strength of the first insulating bonding layer 35 and the second insulating bonding layer 135 may be increased, and the coupling strength of the first bonding pad 36 and the second bonding pad 136 may also be increased.

In an embodiment, a method of forming a semiconductor device may include bonding a stack structure onto a circuit structure. The stack structure may include a plurality of molding layers alternately stacked with a plurality of sacrificial layers. After bonding the stack structure onto the circuit structure, the plurality of sacrificial layers in the stack structure may be removed, and a plurality of electrodes may be formed. An isolation insulating pattern may be formed in a slit that extends through the stack structure.

In an embodiment, a method of forming a semiconductor device may include bonding a stack structure onto a circuit structure. The stack structure may include a plurality of molding layers alternately stacked with a plurality of sacrificial layers. A source line may be formed on the stack structure. A channel structure that extends into the source line through the stack structure may be formed. An isolation insulating pattern may be formed in a slit that extends through the source line and the stack structure. The isolation insulating pattern may include a first section adjacent to the source line and a second section adjacent to the stack structure. The isolation insulating pattern may include a convergence interface between the first section and the second section. The convergence interface may be formed between an end of the channel structure disposed in the source line and a surface of the plurality of electrodes closest to the source line.

In an embodiment, a semiconductor device may include a stack structure formed on a first semiconductor wafer and including a plurality of insulating layers alternately stacked with a plurality of electrodes that replaced a plurality of sacrificial layers. A circuit structure formed on a second wafer and bonded to the stack structure prior to forming the plurality of electrodes may be included. A source line may be disposed on the stack structure. A first insulating layer of the plurality of insulating layers may be closest to the source line. A channel structure extending into the source line through the stack structure may be included. An end of the channel structure may extend into the source line. An isolation insulating pattern may be disposed in a slit that extends through the source line and the stack structure. The isolation insulating pattern may include a convergence interface between a first section adjacent to the source line and a second section adjacent to the stack structure. The convergence interface may be disposed at a level within one of the source line and the first insulating layer.

Although exemplary embodiments of the disclosure are described for illustrative purposes, those skilled in the art will understand that various modifications, additions, and substitutions are possible without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. All changes within the meaning and range of equivalency of the claims are to be included within their scope.

What is claimed is:

1. A semiconductor device comprising:
a circuit structure;
a stack structure bonded onto the circuit structure and including a plurality of molding layers alternately stacked with a plurality of electrodes;
a source line disposed on the stack structure;
a channel structure extending into the source line through the stack structure; and
an isolation insulating pattern disposed in a slit that extends through the source line and the stack structure;
wherein the isolation insulating pattern includes a first section adjacent to the source line and a second section adjacent to the stack structure;
wherein the isolation insulating pattern includes a convergence interface between the first section and the second section; and
wherein the convergence interface is disposed between an end of the channel structure disposed in the source line and a surface of the plurality of horizontal electrodes closest to the source line.

2. The semiconductor device according to claim 1, wherein a surface of the isolation insulating pattern and a surface of the source line are formed in substantially the same plane.

3. The semiconductor device according to claim 1, wherein the convergence interface is disposed between the end of the channel structure and a first molding layer of the plurality of molding layers, wherein the first molding layer is closer to the source line than any of the plurality of molding layers.

4. The semiconductor device according to claim 1, wherein the first section of the isolation insulating pattern has a width different from a width of the second section where the first section is adjacent to the second section, and the convergence interface includes a step.

5. The semiconductor device according to claim 1, wherein a side surface of the first section of the isolation insulating pattern has a different slope from a side surface of the second section of the isolation insulating pattern.

6. The semiconductor device according to claim 1,
wherein the first section of the isolation insulating pattern has an inverted trapezoid shape, and
wherein the second section of the isolation insulating pattern has a trapezoid shape.

7. The semiconductor device according to claim 1, further comprising:
a first insulating bonding layer disposed on the circuit structure;
a first bonding pad in the first insulating bonding layer;
a second insulating bonding layer disposed between the first insulating bonding layer and the stack structure and bonded to the first insulating bonding layer; and
a second bonding pad disposed in the second insulating bonding layer and bonded to the first bonding pad.

8. The semiconductor device according to claim 7, further comprising:
an interlayer insulating layer between the first insulating bonding layer and the stack structure; and
an interconnection disposed in the interlayer insulating layer and connected to the channel structure.

9. The semiconductor device according to claim 8, wherein the second section of the isolation insulating pattern extends into the interlayer insulating layer.

10. The semiconductor device according to claim 8, wherein the channel structure comprises:
a channel pattern connected to the source line; and
a bit plug contacting the channel pattern,
wherein the interconnection contacts the bit plug at a first level.

11. The semiconductor device according to claim 10, wherein the interconnection has a first surface at the first level and a second surface at a second level and opposite the first surface, and wherein an end of the isolation insulating pattern is disposed between the first level and the second level.

12. The semiconductor device according to claim 10,
wherein the channel structure further comprises a core layer that extends into the source line through the stack structure,
wherein the channel pattern surrounds a side surface and an end of the core layer, and
wherein the channel pattern directly contacts the source line.

13. The semiconductor device according to claim 10,
wherein the channel structure further comprises an information storage pattern between the channel pattern and the stack structure, and
wherein an end of the information storage pattern contacts the source line.

14. The semiconductor device according to claim 13, wherein the information storage pattern comprises:
a tunnel layer on the channel pattern;
a charge trap layer on the tunnel layer; and
a blocking layer on the charge trap layer;
wherein the charge trap layer is disposed between the tunnel layer and the blocking layer.

15. A semiconductor device comprising:
a stack structure including a plurality of molding layers alternately stacked with a plurality of electrodes;
a source line disposed on the stack structure;
a channel structure extending into the source line through the stack structure; and
an isolation insulating pattern disposed in a slit that extends through the source line and the stack structure,
wherein the isolation insulating pattern includes a first section adjacent to the source line and a second section adjacent to the stack structure;
wherein a side surface of the isolation insulating pattern includes a convergence interface between the first section and the second section; and
wherein the convergence interface is disposed between an end of the channel structure disposed in the source line and a surface of the plurality of electrodes closest to the source line.

16. The semiconductor device according to claim 15, wherein the plurality of electrodes comprise:
at least one source select line closest to the source line;
at least one drain select line closest to a bit plug; and
a plurality of word lines between the at least one source select line and the at least one drain select line.

17. The semiconductor device according to claim 15, further comprising:
an interlayer insulating layer between a substrate and the stack structure; and
an interconnection disposed in the interlayer insulating layer and connected to the channel structure.

18. The semiconductor device according to claim 17, wherein the channel structure comprises:
a channel pattern connected to the source line;
an information storage pattern between the channel pattern and the stack structure; and
a bit plug contacting the channel pattern;
wherein the interconnection contacts the bit plug.

19. The semiconductor device according to claim 18, wherein an end of the isolation insulating pattern is disposed within the interlayer Insulating layer.

20. The semiconductor device according to claim 18, wherein the Information storage pattern comprises:
a tunnel layer on the channel pattern;
a charge trap layer on the tunnel layer; and
a blocking layer on the charge trap layer;
wherein the charge trap layer is disposed between the tunnel layer and the blocking layer.
